(19) United States
(12) Patent Application Publication
(10) Pub. No.: US 2005/0005207 A1
(43) Pub. Date: Jan. 6, 2005

(54) Method of improving the performance of a transmission protocol using a retransmission timer

(76) Inventor: Thierry Herneque, Paris (FR)

Correspondence Address: SUGHRUE MION, PLLC, 2100 PENNSYLVANIA AVENUE, N.W., SUITE 800, WASHINGTON, DC, 20037, US

(21) Appl. No.: 10/491,146

(22) PCT Filed: Sep. 26, 2002
(86) PCT No.: PCT/FR02/03279

(30) Foreign Application Priority Data
Sep. 28, 2001 (FR) 01/12488

(51) Int. Cl. G01R 31/28

(52) U.S. Cl. 714/712

(57) ABSTRACT

A method of improving the performance of a transmission protocol using a retransmission timer, in which method the retransmission time-out (RTO) of said retransmission timer is varied as a function of statistics on the round-trip time (RTT) including a spread estimate, which method is essentially characterized in that jitter is introduced into said round-trip time (RTT) to control the spread thereof in order to guarantee a minimum value thereof reducing the probability of spurious time-outs of said retransmission timer.

The present invention relates generally to protocols used in telecommunication systems and more particularly to protocols designed for reliable transmission of data over networks that do not themselves guarantee the required reliability. Thus the present invention applies in particular to protocols of the Transmission Control Protocol (TCP) type used in systems operating in accordance with the Transmission Control Protocol/Internet Protocol (TCP/IP) model.

Generally speaking, for reliable transmission of data, these protocols use a mechanism involving acknowledgment by the receiver of received data units and retransmission by the sender of data units that are not acknowledged. A retransmission timer is generally provided so that retransmission is effected automatically if no acknowledgment from the receiver is received before the retransmission timer times out.

A difficult problem to solve, especially in the case of a protocol of the TCP type, is that of selecting the time-out of the retransmission timer. This is because the transmission delay cannot be predicted in a system operating in accordance with the TCP/IP model. In this case, if the retransmission timer time-out is too short, unnecessary retransmissions may be effected, increasing the traffic load in the network unnecessarily, and possibly introducing retransmission ambiguities; conversely, if the retransmission timer time-out is too long, there is the risk of degrading the quality of service in terms of transmission delay.

The above constraints have lead to continuous variation of the retransmission time-out (RTO) of the retransmission timer as a function of statistics on the round-trip time (RTT). Thus is has been proposed to use an expression of the form:
RTO=estimated _mean_RTT+4*estimated_RTT_standard_deviation,
   in which RTO is the current value of the retransmission time-out of the retransmission timer, estimated_mean_RTT is the current estimate of the mean value of the round-trip time, and estimated_RTT_standard_deviation is the current estimate of the standard deviation of the round-trip time. The variables estimated_mean_RTT and estimated_RTT_standard_deviation are obtained by averaging measured RTT values obtained by comparing the time of receiving an acknowledgment with the time of sending the corresponding data.

The TCP interprets timing out of the retransmission timer as congestion in the IP network, and the sending bit rate is then reduced.

For more details on the TCP, see in particular “TCP/IP Illustrated, Volume 1, The Protocols” by W. Richard Stevens.

An increasing number of TCP connections are now set up via packet mode mobile radio networks such as Global System For Mobile communication/General Packet Radio Service (GSM/GPRS) networks and Universal Mobile Telecommunication System (UMTS) networks.

Specific techniques are provided in these mobile radio networks for transmitting data reliably over the radio interface. They include a Radio Link Control (RLC) protocol including retransmission of unacknowledged blocks using an Automatic Repeat reQuest (ARQ) technique.

However, use of the ARQ technique leads to a transmission time that varies as a function of the number of repetitions actually required, which in turn depends directly on the quality of the communication channel, which is highly variable in the case of a radio channel. Now, although the TCP allows variation of the RTO in response to relatively slow variations in the RTT, it cannot vary the RTO in response to fast variations in the RTT, such as occur when using the ARQ technique, for example if radio conditions are suddenly degraded. Another instance of a sudden increase in the RTT is cell reselection, where the network may take several seconds to determine the new location of the mobile terminal and continue the transfer.

A sudden variation in the RTT occurs in this situation, and may cause the retransmission timer to time out.

Clearly the response of the TCP (i.e. retransmission and bit rate reduction) is not suitable in the situation considered here, since in this case the data is simply delayed, for example because it is retransmitted in accordance with the RLC protocol. In particular, data is retransmitted unnecessarily in this situation, and the problem is aggravated by the fact that this kind of retransmission generally does not lead to retransmission of a single data unit, but to retransmission of all the data units contained in a look-ahead window (the theory of the look-ahead window is well known to the person skilled in the art, and is described in the work cited above, for example). This represents a considerable loss of bit rate, especially if wide windows are used (one value that is routinely used being 64 kilobytes). Moreover, this generates duplicate acknowledgments, which in turn generate new retransmissions, and so on.

This problem of spurious time-outs and spurious retransmission is referred to in the following documents, for example:
“TCP Performance over GPRS”, Michael Meyer, WCNC 1999 IEEE Wireless Communications and Networking Conference (Cat. No. 99^{TH}8466), Pt. Vol.3, pp. 1248-1252 Vol.3, Published: Piscataway, N.J., USA, 1999.
“The Eifel Algorithm: Making TCP Robust Against Spurious Retransmission”, Reiner Ludwig, Randy H. Katz, Computer Communication Review, Vol.30, No.1, pp. 30-36, Jan. 2000.

The document “The Eifel Algorithm: Making TCP Robust Against Spurious Retransmission” proposes a solution that consists in adding information to the TCP header specifying if the segment is being transmitted for the first time or retransmitted, which information is copied into the acknowledgment sent back by the receiver and enabling the sender to detect spurious retransmission and therefore to limit the effect thereof to retransmission of a single packet, rather than retransmission of the whole of the look-ahead window. That solution nevertheless involves modifying the TCP and updating all the servers and client terminals wishing to benefit from the enhancement. Moreover, in the case of short TCP connections, such as those encountered on downloading a small HyperText Transfer Protocol (HTTP) object, even the retransmission of only a single packet could represent several tens of percent of the size of the object.

A particular object of the present invention is to avoid the above-mentioned problems by eliminating or at least considerably reducing the probability of spurious time-outs. More generally, an object of the present invention is to improve the performance of such protocols and therefore the performance of telecommunication systems using them.

One aspect of the present invention consists in a method of improving the performance of a transmission protocol using a retransmission timer, in which method the retransmission time-out of said retransmission timer is varied as a function of statistics on the round-trip time including a spread estimate, which method is essentially characterized in that jitter is introduced into said round-trip time to control its spread in order to guarantee a minimum value thereof reducing the probability of spurious time-outs of said retransmission timer.

According to another feature, said round-trip time is obtained by comparing the time of receiving an acknowledgment with the time of sending the corresponding data and said jitter is obtained by delaying at random the routing of said acknowledgments.

According to another feature, in a system operating in accordance with the Transmission Control Protocol/Internet Protocol (TCP/IP) model, said protocol being of the Transmission Control Protocol (TCP) type, said method comprises:
a first step in which TCP segments are detected by analyzing the header of incoming IP datagrams,
a second step in which acknowledgments in the TCP segments detected in this way are detected by analyzing the header of the TCP segments, and
a third step in which routing of the acknowledgments detected in this way is delayed at random.

According to another feature, during said second step, only acknowledgments in TCP segments that do not transport system application layer data are selected.

According to another feature, said method is used for either or both transmission directions.

The present invention further consists in a device for a telecommunication system implementing a transmission protocol using a retransmission timer whose retransmission time-out is varied as a function of statistics on the round-trip time including a spread estimate, which device is essentially characterized in that it comprises means for introducing jitter into said round-trip time to control its spread to guarantee a minimum value thereof reducing the probability of spurious time-outs of said retransmission timer.

According to another feature, said round-trip time is obtained by comparing the time of receiving an acknowledgment with the time of sending the corresponding data and said means for introducing jitter into said round-trip time comprise means for delaying at random the routing of said acknowledgments.

According to another feature, said system operating in accordance with the Transmission Protocol/Internet Protocol model, and said protocol being of the Transmission Control Protocol type, said device comprises:
first means for detecting TCP segments by analyzing the header of incoming IP datagrams,
second means for detecting acknowledgments in the TCP segments detected in this way by analyzing the header of said TCP segments, and
third means for delaying at random the sending of the acknowledgments detected in this way.

According to another feature, said second means further comprise means for selecting only acknowledgments in TCP segments that do not transport system application layer data.

According to another feature, means for introducing jitter into said round-trip time are provided for either or both transmission directions.

According to another feature, said system operating in accordance with the Transmission Control Protocol/Internet Protocol model, said protocol being of the Transmission Control Protocol type, and TCP connections being set up via a packet mode mobile radio network, said device is provided in an equipment of said packet mode mobile radio network.

According to another feature, said packet mode mobile radio network being of the Global System for Mobile communications/General Packet Radio Service type, and said equipment being of the serving GPRS support node or gateway GPRS support node type, said means for introducing jitter into said round-trip time are provided in a Subnetwork Dependent Convergence Protocol layer entity, a GPRS Tunnel Protocol layer entity, or an entity having a relay function and situated above the SNDCP and the GTP.

According to another feature, said mobile radio network being of the Universal Mobile Telecommunication System type and said equipment being of the 3^{rd} generation serving GPRS support node or 3^{rd} generation gateway GPRS support node type, said means for introducing jitter into said round-trip time are provided in a GPRS Tunneling Protocol-User plane layer entity, or in an entity having a relay function situated above the GPRS Tunneling Protocol-User plane.

The invention further consists in packet mode mobile radio network equipment comprising a device of the above kind.

The invention further consists in a mobile station comprising a device of the above kind.

Other objects and features of the present invention will become apparent on reading the following description of embodiments of the invention, given with reference to the accompanying drawings, in which:

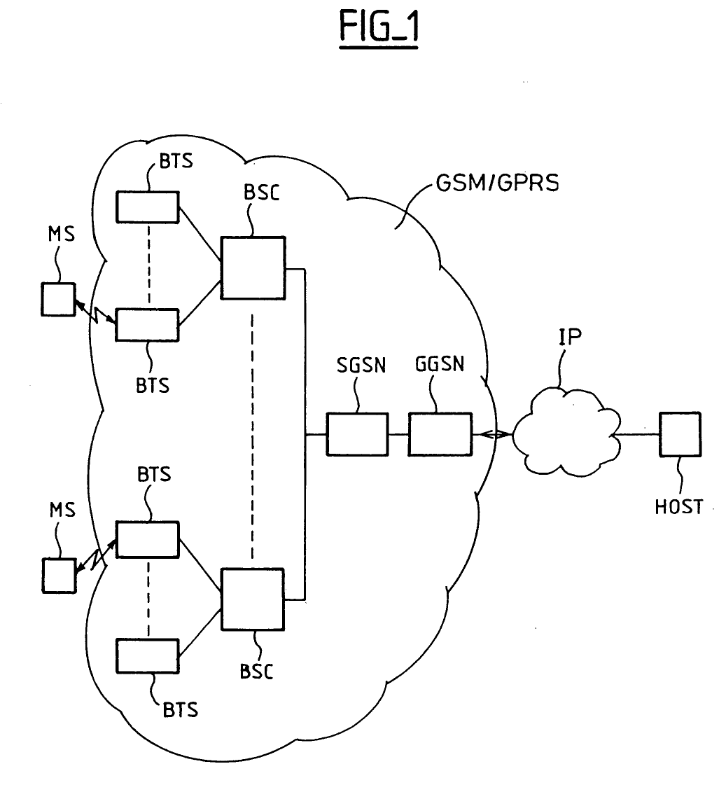

FIG. 1 is a diagram depicting one example of a system to which the present invention may be applied, corresponding by way of example to the situation of a GSM/GPRS packet mode mobile radio network,

FIG. 2 is a diagram depicting the layered organization of a system such as that depicted in FIG. 1, for example,

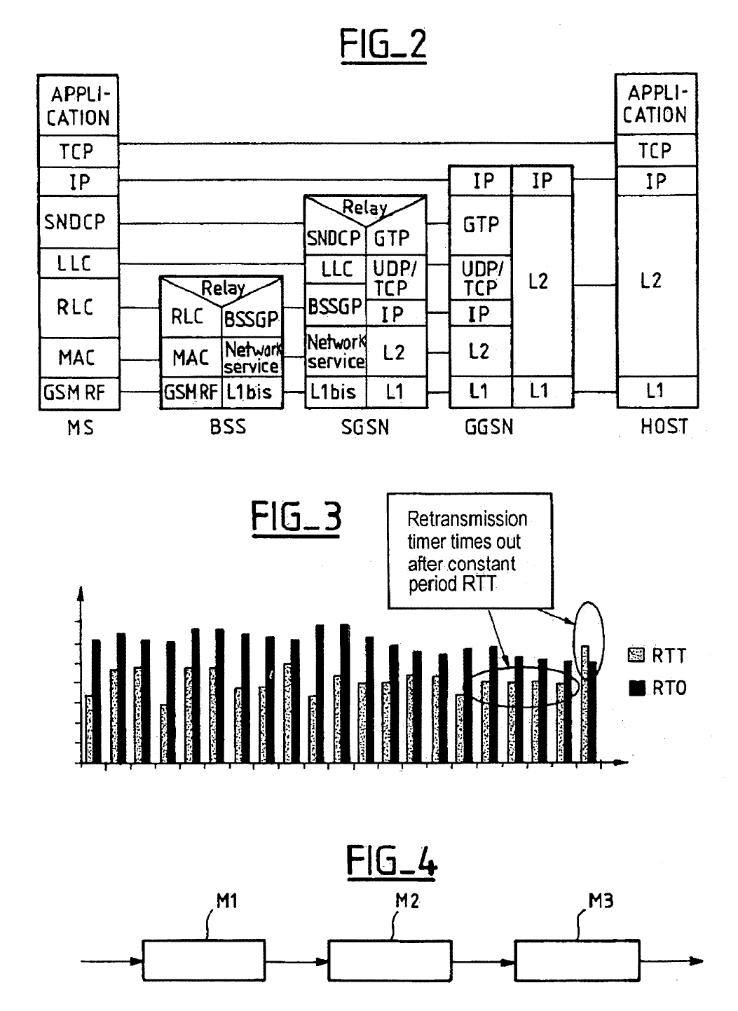

FIG. 3 is a diagram depicting the problem solved by the present invention,

FIG. 4 is a diagram depicting one example of means for implementing a method of the invention,

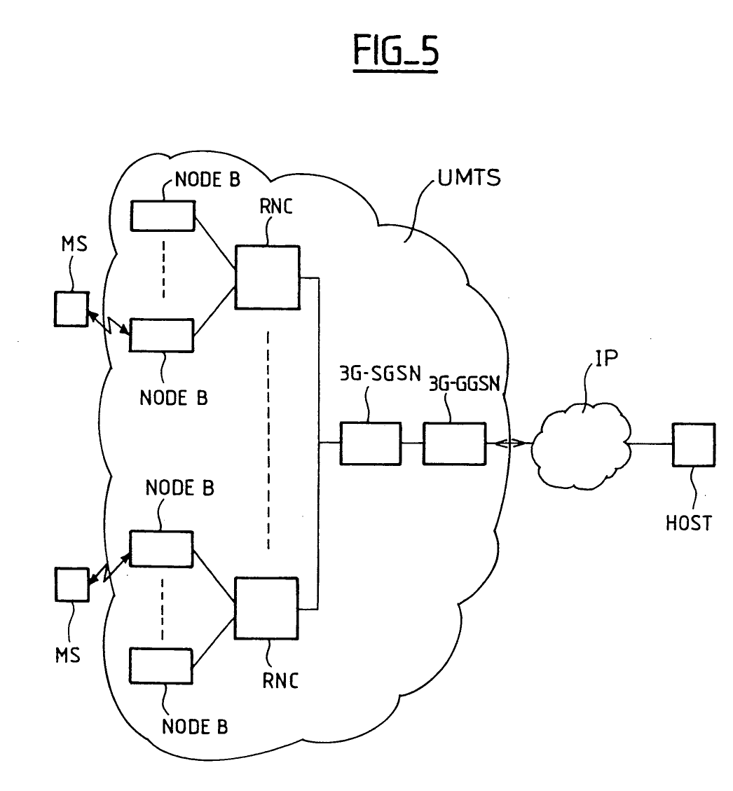

FIG. 5 is a diagram depicting one embodiment of a system to which the present invention may be applied, corresponding by way of example to a UMTS packet mode mobile radio network, and

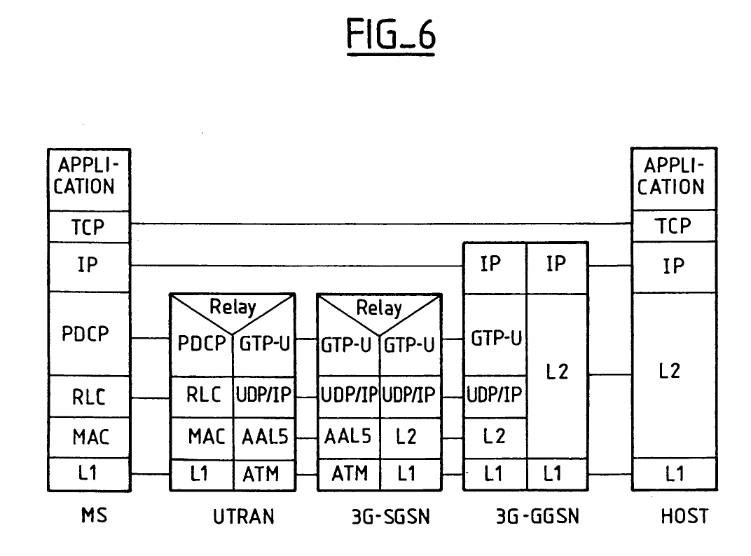

FIG. 6 is a diagram depicting the layered organization of a system such as that depicted in FIG. 5, for example.

FIG. 1 shows one example of a system in which TCP connections may be set up via a packet mode mobile radio network. By way of example, the packet mode mobile radio network is a GSM/GPRS network.

A GSM/GPRS network essentially comprises:
base transceiver stations (BTS) communicating with mobile stations (MS) and base station controllers (BSC), the combination of the base transceiver stations and their base station controllers being called the base station subsystem (BSS) or, more generally, the radio access network, and
serving GPRS support nodes (SGSN) communicating with the BSS and with gateway GPRS support nodes (GGSN), themselves communicating with data networks such as an IP network itself communicating with host machines HOST, as shown in FIG. 1. The combination of the SGSN and the GGSN is generally called the core network.

In the layered architecture used to describe a system such as that depicted in FIG. 1, there are distinguished:
according to the TCP/IP model:
in a host machine HOST:
an application layer,
a transport layer, in this example a Transmission Control Protocol (TCP) layer,
a network layer, in this example an Internet Protocol (IP) layer,
a network-host layer in turn divided into two layers L2 and L1,
in a mobile station MS:
an application layer in dialogue with the HOST application layer,
a transport layer, in this example a TCP layer, in dialogue with the HOST transport layer,
a network layer, in this example an IP layer, in a GGSN:
a network layer, in this example an IP layer, adapted to dialogue with the HOST IP layer (in the simple situation depicted in the figure) or intermediate IP routers,
a network-host layer in turn divided into two layers L2 and L1 adapted to dialogue with the corresponding HOST layers,
according to the model specific to the GSM/GPRS system:
in a mobile station MS:
an adaptation layer for adapting the IP layer to the lower layers, this adaptation layer being called the SubNetwork Dependent Convergence Protocol (SNDCP),
a link layer in turn divided into a logical link control (LLC) layer, a radio link control (RLC) layer, and a medium access control (MAC) layer,
a physical layer called the GSM RF layer,
in the BSS:
1)
a relay function for routing LLC level data units between MS and SGSN,
2)
an RLC layer in dialogue with the MS RLC layer,
a MAC layer in dialogue with the MS MAC layer,
a GSM RF layer in dialogue with the MS GSM RF layer,
3)
a BSS GPRS protocol (BSSGP) layer,
a network service layer,
an L1bis layer,
in a SGSN:
1)
a relay function for routing IP datagrams between MS and GGSN,
2)
an SNDCP layer in dialogue with the MS SNDCP layer,
an LLC layer in dialogue with the MS LLC layer via the LLC level relay of the BSS,
a BSSGP layer in dialogue with the BSS BSSGP layer,
a network service layer in dialogue with the BSS network service layer,
an L1bis layer in dialogue with the BSS L1bis layer,
3)
a GPRS tunnel protocol (GTP) layer,
a User Datagram Protocol/Transmission Control Protocol (UDP/TCP) layer,
an IP layer,
an L2 layer,
an L1 layer,
in a GGSN:
an IP layer in dialogue with the MS IP layer via the IP level relay of the SGSN,
a GTP layer in dialogue with the SGSN GTP layer,
an UDP/TCP layer in dialogue with the SGSN UDC/TCP layer,
an IP layer in dialogue with the SGSN IP layer,
an L2 layer in dialogue with the SGSN L2 layer,
an L1 layer in dialogue with the SGSN L1 layer.

For more details of this layered architecture see Technical Specification 3GPP TS 03.60, version 7.6.0, release 1998, published by the 3^{rd} Generation Partnership Project (3GPP).

Data units (also called TCP segments) are exchanged in accordance with the TCP. The TCP segments are contained in packets (also called IP datagrams) exchanged in accordance with the IP, and the IP datagrams are contained in frames (also called LLC frames) exchanged in accordance with the LLC protocol. The LLC frames are segmented in the RLC/MAC layer to form blocks called RLC data blocks. The RLC data blocks are converted in the physical layer to the format required for transmission over the radio interface.

For a detailed description of the GSM/GPRS system, see the corresponding specifications published by the corresponding standards organizations.

As indicated above, the TCP uses a retransmission timer and the retransmission time-out (RTO) of the retransmission timer is varied continuously in accordance with the following expression:
RTO=estimated_mean_RTT+4*estimated_RTT_standard_deviation
   in which RTO is the current value of the retransmission timer time-out, estimated_mean_RTT is the current estimate of the mean round-trip time, and estimated_RTT_standard_deviation is the current estimate of the standard deviation of the round-trip time. The variables estimated_mean_RTT and estimated_RTT_standard_deviation are obtained by averaging measured RTT values obtained by comparing the time of receiving an acknowledgment with the time of sending the corresponding data.

The applicant has observed that a spurious retransmission timer time-out occurs when, after a period in which RTT is relatively constant for consecutive TCP segments, i.e. after a period in which the RTT standard deviation is low, RTT is subject to a sudden or transient increase (called a “glitch”) which increases it above the current RTO value.

This problem may be illustrated with reference to FIG. 3, for example. FIG. 3 depicts a population of RTT samples (here numbered from 1 to 21), and the corresponding values obtained for RTO. In this example, the RTT samples 17 to 20 have a virtually constant value, leading to a progressive decrease in the current value of the RTO, and sample 21 is subject to a sudden increase (glitch), causing it to rise above the current value of RTO, which cannot be adjusted fast enough to take account of this.

To prevent this problem, the present invention proposes to introduce an intentional phase variation (jitter) into the round-trip time RTT to control its spread (in particular the standard deviation in this example), in order to guarantee a minimum value reducing the probability of a spurious retransmission timer time-out. In other words, the present invention avoids periods in which RTT is virtually constant, or artificially increases the RTT standard deviation (or, more generally, any parameter characteristic of its spread), or artificially increases the retransmission time-out RTO of the retransmission timer, in order to reduce the probability of spurious retransmission timer time-outs, or takes account of fast and consecutive increases in the RTT, retaining a sufficient margin between the RTO and the RTT.

Another advantage of the present invention is that this result may be obtained without modifying existing implementations of the TCP.

Since in practice the jitter introduced can only be a delay, this increases the value of estimated_mean_RTT. Any resulting problems may be compensated by increasing the width of the user TCP window simply by configuring the software implementing the TCP (the theory of this kind of window is also well known to the person skilled in the art, and is described in the above-mentioned work, for example).

One example of an algorithm for delaying at random the routing of acknowledgments is described next.

The following notation is used:
ack_1, ack_2, . . . , ack_n, . . . denotes a series of received TCP acknowledgments,
T_ack_1, T_ack_2, . . . , T_ack_(n), . . . denotes the times at which the TCP acknowledgments are received,
T_forward_ack_1, T_forward_ack_2, . . . ,
T_forward_ack_(n), . . . denotes the times at which the TCP acknowledgments are retransmitted after application of a delay.
N is the index of the current received TCP acknowledgment.
T_forward_ack(N) is determined by means of the following expression, for example:
T_forward_ack_(N)=T_ack_(N)+rand( )*Max_Delay
   where rand ( ) is a function for supplying a random number in the range [0, 1[, and Max_Delay is a predetermined maximum time delay.

Max_Delay is advantageously a parameter that may be configured by the mobile radio network operator. Thus the spread introduced artificially may be as extensive as necessary and adapted to each situation in which the present invention is used.

The present invention also provides a device for implementing a method according to the invention.

Generally speaking, a device according to the invention comprises means for introducing jitter into the round-trip time to control its spread, in order to guarantee a minimum value thereof reducing the probability of spurious retransmission timer time-outs.

The round-trip time being itself obtained by comparing the time of receiving an acknowledgment with the time of sending the corresponding data, these means advantageously themselves comprise means for delaying at random the routing of acknowledgments.

Generally speaking, the present invention may be implemented in any telecommunication system equipment, for example any equipment of a system of the type depicted in FIGS. 1 and 2.

The present invention is advantageously implemented in a packet mode mobile radio network equipment, for example an SGSN or a GGSN in a system of the type depicted in FIGS. 1 and 2.

In this case, the invention is not implemented in the TCP layer itself, but in a layer such as the SNDCP or GTP layer, for example, or in the relay function between these two protocols in the case of a SGSN, or the GTP layer in the case of GGSN. The data units, packets or IP datagrams exchanged at the level of the IP layer may be recovered in either of these layers.

As a general rule, each layer adds a header to data units that it receives from the next higher layer before passing them to the next lower layer. In this example the header of IP datagrams contains a field indicating the type of protocol (for example TCP or UDP) and the header of the TCP segments contains a field reserved for TCP acknowledgments.

In this case, there may be provided, for implementing the invention, as depicted in FIG. 4:
first means M1 for detecting TCP segments by analyzing the header of incoming IP datagrams,
second means M2 for detecting acknowledgments contained in the TCP segments detected in this way by analyzing the header of those TCP segments, and
third means M3 for delaying at random the routing of acknowledgments detected in this way.

The second means advantageously further comprise means for selecting only acknowledgments contained in TCP segments that do not transport application layer data.

The above means may take the form of software, of course.

In the case of a Global System for Mobile communications/General Packet Radio Service (GSM/GPRS) packet mode mobile radio network, the above means may be provided in a Subnetwork Dependent Convergence Protocol (SNDCP) layer entity or a GPRS Tunnel Protocol (GTP) layer entity or in the relay function between the SNDCP and the GTP, a serving GPRS support node (SGSN), or a gateway GPRS support node (GGSN).

A device according to the invention could also be used in a mobile station.

Moreover, because the present invention may be used for both transmission directions, in each possible implementation scenario each equipment will be considered as a sender (source) or receiver (destination), as appropriate.

Moreover, the GSM/GPRS network referred to in the foregoing description is merely one example of a mobile radio network to which the present invention may be applied.

The invention may of course be applied to other types of networks, such as UMTS networks in particular.

Thus FIG. 5 shows one example of a system in which TCP connections may be set up via a UMTS packet mode mobile radio network.

In the UMTS, the radio access network is called the UMTS terrestrial radio access network (UTRAN), a base station is called a Node B, a base station controller is called a radio network controller (RNC), and the SGSN and the GGSN are respectively called the 3G-SGSN and the 3G-GGSN, where 3G stands for 3^{rd} generation.

Generally speaking, the UMTS is also covered by standards and for more information reference may be had to the corresponding specifications published by the corresponding standards organizations.

FIG. 6 shows the layered architecture of a system such as that depicted in FIG. 5. This kind of architecture is not described again in detail here, firstly because is has points in common with the architecture shown in FIG. 2, and secondly because more details can be obtained from Technical Specification 3GPP TS 23.060, version 4.1.0, release 4, published by the 3^{rd} Generation Partnership Project (3GPP).

The problem solved by the present invention in this type of system is entirely similar to what has been described already in relation to a GSM/GPRS system.

Similarly, the present invention may be implemented in any equipment of a system of the type depicted in FIGS. 5 and 6.

The present invention is advantageously implemented in a packet mode mobile radio network equipment such as a 3G-SGSN or a 3G-GGSN, for example, in a system of the type depicted in FIGS. 5 and 6.

In this type of system, the invention may be implemented in a GPRS Tunneling Protocol-User plane (GTP-U) layer entity, for example, the role of which is to transport user IP traffic of the access network (UTRAN) to the core network and then within the core network, or in an entity having a relay function and situated above the GTP-U layer.

A device according to the invention could also be used in a mobile station (MS) or a user equipment (UE).

The present invention also consists in a packet mode mobile radio network equipment (such as a SGSN, a 3G-SGSN, a GGSN or a 3G-GGSN) comprising a device for implementing the present invention.

The present invention also consists in a mobile station (MS) or a user equipment (UE) comprising a device for implementing the present invention.

1. A method of improving the performance of a transmission protocol using a retransmission timer, in which method the retransmission time-out (RTO) of said retransmission timer is varied as a function of statistics on the round-trip time (RTT) including a spread estimate, which method is characterized in that jitter is introduced into said round-trip time (RTT) to control the spread thereof in order to guarantee a minimum value thereof reducing the probability of spurious time-outs of said retransmission timer.

2. A method according to claim 1, characterized in that said round-trip time is obtained by comparing the time of receiving an acknowledgment with the time of sending the corresponding data and said jitter is obtained by delaying at random the routing of said acknowledgments.

3. A method according to claim 2, characterized in that, in a system operating in accordance with the Transmission Control Protocol/Internet Protocol (TCP/IP) model, said protocol being of the Transmission Control Protocol (TCP) type, said method comprises:
a first step in which TCP segments are detected by analyzing the header of incoming IP datagrams,
a second step in which acknowledgments in the TCP segments detected in this way are detected by analyzing the header of the TCP segments, and
a third step in which routing of the acknowledgments detected in this way is delayed at random.

4. A method according to claim 3, characterized in that, during said second step, only acknowledgments in TCP segments that do not transport system application layer data are selected.

5. A method according to claim 1, characterized in that it is used for either or both transmission directions.

6. A device for a telecommunication system implementing a transmission protocol using a retransmission timer whose retransmission time-out (RTO) is varied as a function of statistics on the round-trip time (RTT) including a spread estimate, which device is characterized in that it comprises means for introducing jitter into said round-trip time (RTT) to control its spread to guarantee a minimum value thereof reducing the probability of spurious time-outs of said retransmission timer.

7. A device according to claim 6, characterized in that said round-trip time is obtained by comparing the time of receiving an acknowledgment with the time of sending the corresponding data and said means for introducing jitter into said round-trip time (RTT) comprise means for delaying at random the routing of said acknowledgments.

8. A device according to claim 6, characterized in that, said system operating in accordance with the Transmission Control Protocol/Internet Protocol (TCP/IP) model, and said protocol being of the Transmission Control Protocol (TCP) type, said device comprises:
first means (M1) for detecting TCP segments by analyzing the header of incoming IP datagrams,
second means (M2) for detecting acknowledgments in the TCP segments detected in this way by analyzing the header of said TCP segments, and
third means (M3) for delaying at random the sending of acknowledgments detected in this way.

9. A device according to claim 8, characterized in that said second means further comprise means for selecting only acknowledgments in TCP segments that do not transport system application layer data.

10. A device according to claim 6, characterized in that means for introducing jitter into said round-trip time (RTT) are provided for either or both transmission directions.

11. A device according to claim 6, characterized in that, said system operating in accordance with the Transmission Control Protocol/Internet Protocol (TCP/IP) model, said protocol being of the Transmission Control Protocol (TCP) type, and TCP connections being set up via a packet mode mobile radio network, said device is provided in an equipment of said packet mode mobile radio network.

12. A device according to claim 11, characterized in that, said packet mode mobile radio network being of the Global System for Mobile communications/General Packet Radio Service (GSM/GPRS) type, and said equipment being of the serving GPRS support node (SGSN) or gateway GPRS support node (GGSN) type, said means for introducing jitter into said round-trip time (RTT) are provided in a Subnetwork Dependent Convergence Protocol (SNDCP) layer entity, a GPRS Tunnel Protocol (GTP) layer entity, or an entity having a relay function and situated above the SNDCP and the GTP.

13. A device according to claim 11, characterized in that, said mobile radio network being of the Universal Mobile Telecommunication System (UMTS) type and said equipment being of the 3^{rd} generation serving GPRS support node (3G-SGSN) or 3^{rd} generation gateway GPRS support node (3G-GGSN) type, said means for introducing jitter into said round-trip time (RTT) are provided in a GPRS Tunneling Protocol-User plane (GTP-U) layer entity or in an entity having a relay function situated above the GPRS Tunneling Protocol-User plane.

14. Packet mode mobile radio network equipment characterized in that it comprises a device according to claim 11.

15. A mobile station characterized in that it comprises a device according to claim 11.
